(19) United States
(12) Patent Application Publication
(10) Pub. No.: US 2007/0122917 A1
(43) Pub. Date: May 31, 2007

(54) Forming method of ferroelectric capacitor and manufacturing method of semiconductor device

(75) Inventors: Mitsushi Fujiki, Kawasaki (JP); Kenkichi Suezawa, Kawasaki (JP); Makoto Takahashi, Kawasaki (JP); Ko Nakamura, Kawasaki (JP); Wensheng Wang, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/407,207

(22) Filed: Apr. 20, 2006

(30) Foreign Application Priority Data
Nov. 28, 2005 (JP) 2005-342145

(51) Int. Cl. H01L 21/00; H01L 21/8242

(52) U.S. Cl. 438/3; 438/240

(57) ABSTRACT

Disclosed is a ferroelectric capacitor forming method of allowing a FeRAM to be stably mass-produced. In forming the ferroelectric capacitor for the FeRAM, a PZT layer is formed on a lower electrode layer by a sputtering method. Then, a first RTA treatment for crystallizing the PZT is performed in an environment controlled such that predetermined capacitor performance such as a data holding property can be obtained regardless of the amount of a target previously used (used hours) in the sputtering method. For example, the O₂ gas flow rate is controlled in an appropriate range during the first RTA treatment. Thereafter, formation of an upper electrode layer or a second RTA treatment is performed. As a result, the ferroelectric capacitor having predetermined capacitor performance can be formed with high yield, so that the FeRAM can be stably mass-produced.

### CROSS-REFERENCE TO RELATED APPLICATIONS

This application is based upon and claims the benefits of priority from the prior Japanese Patent Application No. 2005-342145, filed on Nov. 28, 2005, the entire contents of which are incorporated herein by reference.

### BACKGROUND OF THE INVENTION

1. Field of the Invention

The present invention relates to a forming method of a ferroelectric capacitor and a manufacturing method of a semiconductor device. More particularly, the present invention relates to a forming method of a ferroelectric capacitor having a dielectric layer made of a ferroelectric material and a manufacturing method of a semiconductor device having the ferroelectric capacitor.

2. Description of the Related Art

Conventionally, there have been promoted development and manufacture of a nonvolatile semiconductor memory using a property of a ferroelectric substance of which a polarized state can be reversibly controlled by an external electric field, namely, a FeRAM (Ferroelectric Random Access Memory).

As in a DRAM (Dynamic Random Access Memory), the FeRAM has a memory cell structure composed of a switching transistor and a capacitor, and is manufactured using ferroelectric materials for a dielectric layer of the capacitor. For the ferroelectric materials, for example, lead zirconate titanate (Pb(Zr, Ti)O₃, PZT) is used.

A ferroelectric capacitor for the FeRAM is obtained by forming a lower electrode layer, a ferroelectric layer and an upper electrode layer, for example, using a sputtering method. At the formation of the ferroelectric layer, an annealing treatment is performed under a predetermined condition for crystallizing the ferroelectric material in an amorphous state after film formation (see, e.g., Japanese Unexamined Patent Application Publication Nos. 2001-126955 and 2002-246564).

Tetragonal PZT has a polarization axis in the (001) direction. Therefore, the PZT has the largest polarization value when being oriented to c-axis. However, it is generally difficult to orient the PZT to c-axis on a polycrystalline substrate to form a layer of the PZT.

Therefore, when forming the ferroelectric capacitor for the FeRAM using the PZT, a lower electrode layer is first formed using platinum (Pt) of which a lattice constant is relatively close to that of the PZT. Pt is easily oriented to a (111) face as a closest-packed face when forming a film, for example, using a DC sputtering method. Further, on the lower electrode layer, a PZT layer is formed such that the (111) face is preferentially oriented. When thus forming the PZT layer, a switching (polarity inversion) direction forms an angle of 45° to the inversion electric field. Therefore, a relatively large polarization value capable of being practically used sufficiently for a nonvolatile memory is obtained although the value falls short of a value obtained when forming the PZT layer such that the (001) face is preferentially oriented. As a result, a FeRAM having an excellent property and productivity can be formed.

When forming the PZT layer on the lower electrode layer formed using Pt, for example, a RF sputtering method is used. The PZT immediately after the sputter deposition is in an amorphous state and therefore, is crystallized by a subsequent annealing treatment. The annealing treatment for crystallizing the PZT is usually performed in an environment where oxygen (O₂) is present. In a conventional FeRAM formation, when thus forming the PZT layer, the film formation condition or the annealing condition is appropriately selected so that a (111) face of the PZT can be oriented preferentially.

However, in mass production of FeRAMs, the following problem occurs. That is, in the case of forming the PZT layer by the sputtering method using a PZT target, when the amount of the PZT target used increases (longer used hours are required), predetermined electric characteristics of the obtained ferroelectric capacitor deteriorate depending on the annealing condition for the subsequent PZT crystallization, and as a result, a yield may decrease.

FIG. 9 shows a relationship between the amount of the PZT target used and the yield of the ferroelectric capacitor. In FIG. 9, a horizontal axis shows electric energy (kWh) supplied to the PZT target, and a vertical axis shows a yield (%) of the ferroelectric capacitor. The yield herein is evaluated based on a ratio of capacitors (capacitors having fixed capacitor performance) allowed to pass a predetermined reliability test (for example, a data holding property test after leaving capacitors at high temperatures) to the capacitors of which the operations are previously checked.

The yield of the ferroelectric capacitor formed under a certain annealing condition has the following tendency as shown in FIG. 9. That is, until a certain amount of the PZT target used, the yield generally keeps a high value, whereas when the amount of the PZT target used exceeds a fixed value, the yield decreases.

This decrease in the yield is caused by a single bit defect. On the other hand, in a conventional optimizing method based on the crystal orientation property or polarization value of the PZT, there is currently recognized only an average structure of crystals or electric characteristics in a state where a number of cell capacitors are joined. In order to stably perform mass production of FeRAMs for a long period of time, manufacturing process conditions for FeRAMs must be further optimized.

### SUMMARY OF THE INVENTION

In view of the foregoing, it is an object of the present invention to provide a ferroelectric capacitor forming method capable of forming with high yield a ferroelectric capacitor having predetermined capacitor performance. It is another object of the present invention to provide a manufacturing method of a semiconductor device having the thus formed ferroelectric capacitor with predetermined capacitor performance.

To accomplish the above object, according to the present invention, there is provided a method for forming a ferroelectric capacitor having a dielectric layer made of a ferroelectric material. This forming method comprises the steps of: forming a lower electrode layer, forming the ferroelectric layer on the lower electrode layer using a sputtering method, performing, after formation of the ferroelectric layer, a thermal treatment in an environment controlled such that predetermined capacitor performance can be obtained regardless of the amount of a target used in the sputtering method, and forming at least a part of an upper electrode layer on the ferroelectric layer after the thermal treatment.

To accomplish another object, according to the present invention, there is also provided a method for manufacturing a semiconductor device having a ferroelectric capacitor. This manufacturing method comprises the steps of: forming a lower electrode layer, forming a ferroelectric layer on the lower electrode layer using a sputtering method, performing, after formation of the ferroelectric layer, a thermal treatment in an environment controlled such that predetermined capacitor performance can be obtained irrespective of the amount of a target used in the sputtering method, and forming at least a part of an upper electrode layer on the ferroelectric layer after the thermal treatment.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows one example of a formation flow of a FeRAM.

FIG. 2 is a schematic cross-sectional view of an essential part of one example of a FeRAM.

FIG. 3 shows a relationship between an O₂ gas flow rate during a first RTA treatment and an orientation rate in a PZT (222) face.

FIG. 4 shows a relationship between an O₂ gas flow rate during a first RTA treatment and switching electrical charges of a ferroelectric capacitor.

FIG. 5 shows a relationship between an O₂ gas flow rate during a first RTA treatment and an integrated intensity in a PZT (101) face.

FIG. 6 shows a relationship between an O₂ gas flow rate during a first RTA treatment and an integrated intensity in a PZT (100) face.

FIG. 7 shows a relationship between an O₂ gas flow rate during a first RTA treatment and an integrated intensity in a PZT (222) face.

FIG. 8 shows a relationship between an O₂ gas flow rate during a first RTA treatment and an orientation rate in a PZT (222) face.

FIG. 9 shows a relationship between the amount of a PZT target used and a yield of a ferroelectric capacitor.

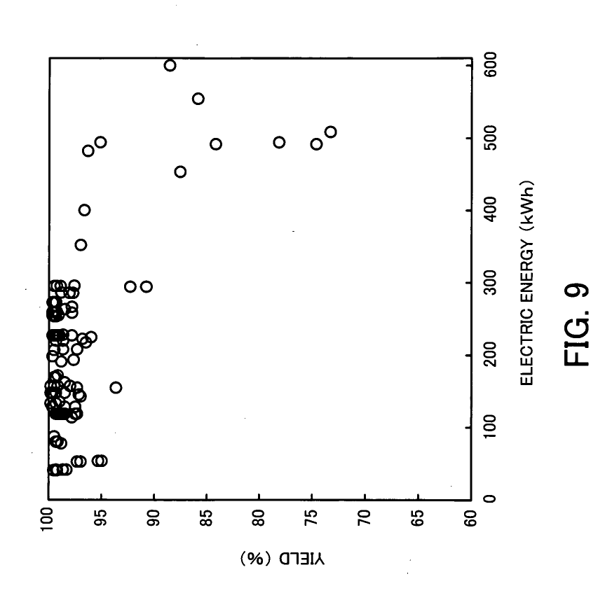

### DESCRIPTION OF THE PREFERRED EMBODIMENTS

Preferred embodiments of the present invention will be described below with reference to the accompanying drawings, wherein like reference numerals refer to like elements throughout.

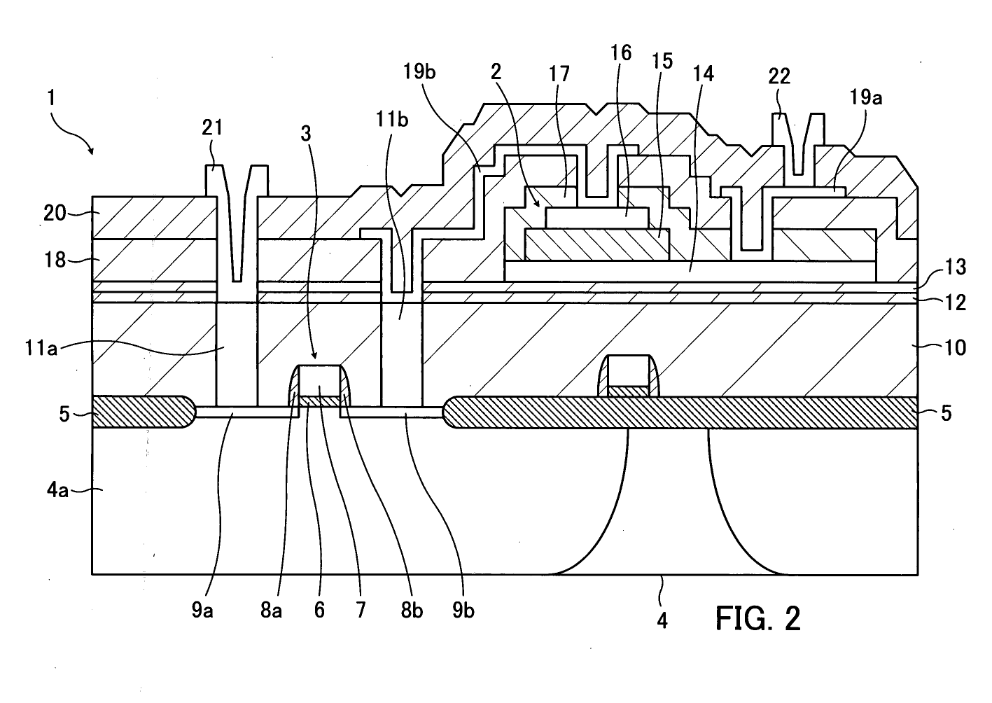

FIG. 2 is a schematic cross-sectional view of an essential part of one example of a FeRAM.

A FeRAM 1 has a ferroelectric capacitor 2 which holds data and a MOS (Metal Oxide Semiconductor) transistor 3 which accesses the capacitor 2.

The MOS transistor 3 is formed, using a silicon (Si) substrate 4, in an element region within a predetermined conductivity type well 4a partitioned by an element isolation region 5 made of a field oxide film. In the MOS transistor 3, a gate electrode 7 serving as a word line of the FeRAM 1 is formed on the Si substrate 4 through a gate insulating film 6. Further, sidewall insulating films 8a and 8b are formed on both sides of the gate electrode 7. Further, predetermined conductivity type impurity diffusion regions 9a and 9b are formed within the Si substrate 4 on both sides of the gate electrode 7. Thus, the MOS transistor 3 is formed.

On a wafer having formed thereon this MOS transistor 3, an interlayer insulating film 10 made of silicon oxide (SiO₂) is formed. Further, plugs 11a and 11b made of tungsten (W) are formed to penetrate this interlayer insulating film 10. The plugs 11a and 11b are connected to the impurity diffusion regions 9a and 9b, respectively. Further, on the interlayer insulating film 10, an oxidization preventive film 12 made of oxidized silicon nitride (SiON), and a SiO₂ film 13 are formed and thereon, the ferroelectric capacitor 2 is formed.

The ferroelectric capacitor 2 is composed of a lower electrode layer 14, a dielectric layer 15 and an upper electrode layer 16.

The lower electrode layer 14 may have, for example, a structure that a Pt film is laminated on an aluminum oxide (Al₂O₃) film. Further, the layer 14 may be formed by using a film of iridium (Ir), ruthenium (Ru), ruthenium oxide (RuO₂), strontium ruthenate (SrRuO₃) or other conductive oxides, or by laminating these films in an appropriate combination. Note, however, that the lower electrode layer 14 preferably has a laminated structure of an Al₂O₃ film and a Pt film in view of morphology or productivity.

The dielectric layer 15 is formed, for example, by using PZT as a ferroelectric substance. Further, the upper electrode layer 16 is formed, for example, by using an iridium oxide (IrOₓ) film.

The lower electrode layer 14, dielectric layer 15 and upper electrode layer 16 of the ferroelectric capacitor 2 are formed in a tiered stand shape. Further, an encapsulated layer 17 is formed by using PZT so as to cover the layers 14, 15 and 16.

Through contact holes penetrating the encapsulated layer 17 and the interlayer insulating layer 18 made of SiO₂, local wiring patterns 19a and 19b are connected to the lower electrode layer 14 and upper electrode layer 16 of the ferroelectric capacitor 2, respectively. Among these, the pattern 19b connected to the upper electrode layer 16 penetrates the interlayer insulating film 18, the SiO₂ film 13 and the oxidization preventive film 12 so as to be connected to the plug 11b connected to the impurity diffusion region 9b of the MOS transistor 3. As a result, the ferroelectric capacitor 2 and the MOS transistor 3 are electrically connected with each other.

The whole element structure is covered with a passivation film 20 made of SiO₂. Further, an electrode 21 which penetrates the passivation film 20, the interlayer insulating film 18, the SiO₂ film 13 and the oxidization preventive film 12 is connected to the plug 11a connected to the other impurity diffusion region 9a of the MOS transistor 3. The electrode 21 serves as a bit line of the FeRAM 1. Further, another electrode 22 which penetrates the passivation film 20 is connected to the local wiring pattern 19a connected to the lower electrode layer 14.

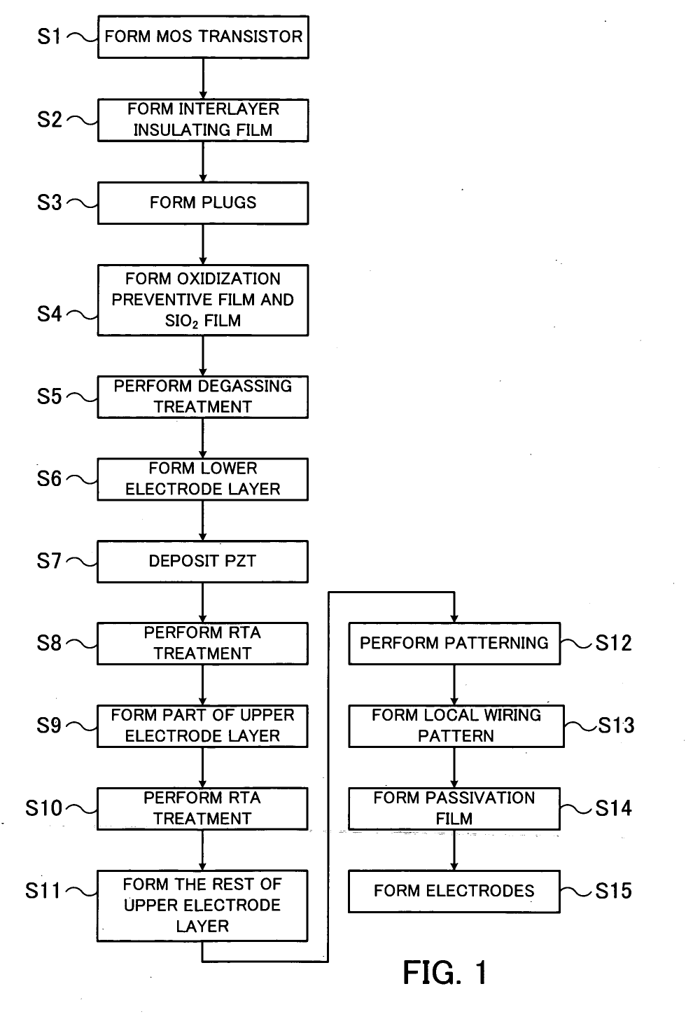

The FeRAM 1 having such a constitution can be formed, for example, according to a flow as shown in the following FIG. 1.

FIG. 1 shows one example of a formation flow of a FeRAM.

According to an ordinary method, the gate insulating film 6, the gate electrode 7, the sidewall insulating films 8a and 8b, and the impurity diffusion regions 9a and 9b are first formed in the element region partitioned by the element isolation region 5 to thereby form the MOS transistor 3 (step S1).

Next, on the wafer having formed thereon the MOS transistor 3, SiO₂ having a film thickness of about 1000 nm is deposited using a CVD (Chemical Vapor Deposition) method and is flattened using CMP (Chemical Mechanical Polishing) to thereby form the interlayer insulating film 10 (step S2).

Further, the contact holes which communicate with the impurity diffusion regions 9a and 9b are formed in the interlayer insulating film 10. Then, W is deposited on the whole surface of the contact holes and is similarly flattened using CMP to thereby form the plugs 11a and 11b (step S3).

Thereafter, the oxidization preventive film 12 made of SiON, and the SiO₂ film 13 are formed to have a film thicknesses of about 100 nm and about 130 nm, respectively (step S4). Then, the films 12 and 13 are subjected to an annealing treatment at about 650° C. for 30 minutes in a nitrogen (N₂) atmosphere to thereby perform a degassing treatment (step S5).

Next, in the case of constituting the lower electrode layer 14, for example, by a Pt/Al₂O₃ laminated structure, an Al₂O₃ film with a film thickness of about 20 nm and a Pt film with a film thickness of about 155 nm are sequentially deposited on the whole surface using a DC sputtering method to thereby form the lower electrode layer 14 (step S6).

Next, using a RF sputtering method, PZT with a film thickness of about 150 nm is deposited on the lower electrode layer 14 (step S7). During the deposition of the PZT by the RF sputtering method, there is used a PZT target previously formed at a composition ratio required for the dielectric layer 15. The PZT deposited on the lower electrode layer 14 using this PZT target is in an amorphous state.

In order to crystallize the PZT in an amorphous state, a Rapid Thermal Anneal (RTA) treatment is then performed using a lamp annealing device (step S8). The RTA treatment at this stage is performed mainly for forming crystal grains of the PZT. The RTA treatment is performed under conditions at about 563° C. for about 90 seconds in an atmosphere of a mixed gas composed of an O₂ gas and argon (Ar) gas with a predetermined partial pressure. The O₂ gas volume in the mixed gas during the RTA treatment is set to about 0.1% by volume to 50% by volume, preferably about 1% by volume to 5% by volume, more preferably about 2% by volume to 5% by volume. Detailed conditions of the O₂ gas volume during the RTA treatment, and a relationship between the amount of the PZT target used and the O₂ gas volume during the RTA treatment are described later.

After the RTA treatment, an IrOₓ film with a film thickness of about 50 nm serving as a part of the upper electrode layer 16 is first formed by a DC sputtering method (step S9).

Thereafter, the RTA treatment is performed under the conditions at about 708° C. for about 20 seconds in an atmosphere of an O₂/Ar mixed gas (an O₂ gas: about 1% by volume, the rest: an Ar gas) (step S10). The RTA treatment at this stage is performed mainly for growing the crystal grains formed by the previous RTA treatment. By the RTA treatment (referred to as a “first RTA treatment”) in the step S8 and the RTA treatment (referred to as a “second RTA treatment”) in the step S10, the dielectric layer 15 made of the PZT having a predetermined crystalline structure is formed.

After the RTA treatment in the step S10, an IrOₓ film with a film thickness of about 200 nm is formed on the IrOₓ film previously formed in the step S9 to thereby form the upper electrode layer 16 with a film thickness of about 250 nm in total (step S11).

Further, patterning and etching are sequentially performed on the upper electrode layer 16, the dielectric layer 15 and the lower electrode layer 14 to allow the respective layers to remain in a tiered stand shape only in a predetermined region. Thus, the ferroelectric capacitor 2 is formed (step S12).

Thereafter, the interlayer insulating film 18 is formed on the whole surface and then, contact holes which communicate with the lower electrode layer 14, the upper electrode layer 16 and the plug 11b are formed in the film 18, respectively. Then, the local wiring patterns 19a and 19b are formed (step S13).

Further, the passivation film 20 is formed on the whole surface (step S14). Then, contact holes which communicate with the plug 11a and the local wiring pattern 19a are formed in the film 20, respectively. Then, the electrodes 21 and 22 are formed in each of the contact holes (step S15). Through the above-described steps, the FeRAM 1 is completed.

Herein, the conditions for the first RTA treatment in the step S8 will be described in more detail.

During the first RTA treatment, when the O₂ gas volume is set to about 0.1% by volume to 50% by volume as described above, the PZT in an amorphous state after the sputter deposition can be crystallized. Note, however, that in order to obtain the ferroelectric capacitor 2 which indicates switching electrical charges QSW of a fixed value or more, the O₂ gas volume during the first RTA treatment is preferably set to about 1% by volume to 5% by volume. It is known that a crystal orientation property of the PZT in the dielectric layer 15 has a certain level of influence on the switching electrical charges QSW. Further, the crystal orientation property of the PZT is influenced by the O₂ gas volume during the first RTA treatment. That is, the O₂ gas volume during the first RTA treatment acts as one of control parameters for forming the PZT which indicates a desired crystal orientation property.

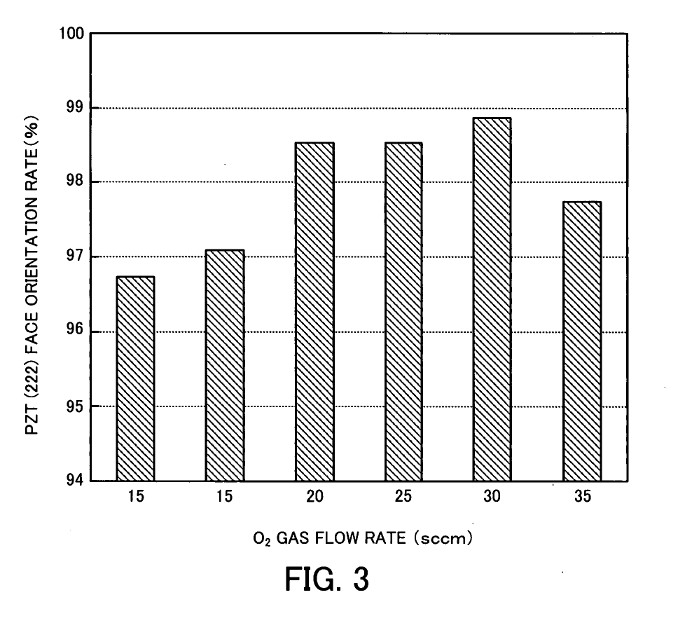

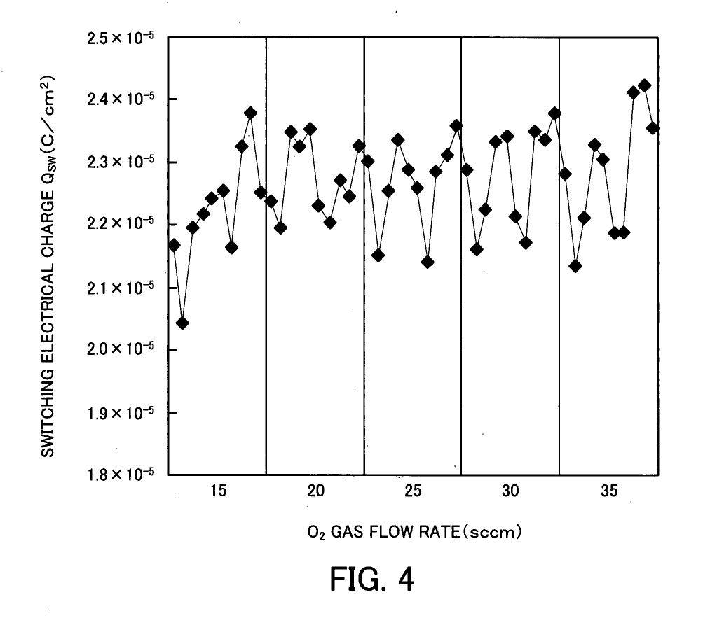

FIG. 3 shows a relationship between an O₂ gas flow rate during the first RTA treatment and an orientation rate in the PZT (222) face. FIG. 4 shows a relationship between an O₂ gas flow rate during the first RTA treatment and switching electrical charges of the ferroelectric capacitor. In FIG. 3, a horizontal axis shows the O₂ gas flow rate (sccm) during the first RTA treatment, and a vertical axis shows the orientation rate (%) in the PZT (222) face. Further, in FIG. 4, a horizontal axis shows the O₂ gas flow rate (sccm) during the first RTA treatment, and a vertical axis shows the switching electrical charges QSW (C/cm²) of the ferroelectric capacitor 2. With respect to the switching electrical charge QSW, each of two ferroelectric capacitors 2 is measured on five different points (ten points in total) in each O₂ gas flow rate.

In FIGS. 3 and 4, 1 sccm=1 ml/min (0° C., 101.3 kPa). Further, under the conditions at about 563° C. for about 90 seconds, the first RTA treatment is performed as follows. That is, a wafer including the lower electrode layer 14 having sputtered thereon the PZT is set within a chamber of the lamp annealing device. Then, a mixed gas composed of an O₂ gas and an Ar gas is put in circulation while changing the O₂ gas flow rate in a range of 15 to 35 sccm to bring the total flow rate to 2000 sccm. The orientation rate in the PZT (222) face is determined as follows. That is, after the second RTA treatment, measurement using an X-ray diffractometer (XRD) is performed to determine integrated intensities in the respective crystal planes from the diffraction peaks of a PZT (101) face, a (100) face and a (222) face. Then, calculation is performed using the following formula:

Orientation rate (%) in PZT (222) face={integrated intensity in PZT (222) face}/[{integrated intensity in PZT (100) face}+{integrated intensity in PZT (101) face}+{integrated intensity in PZT (222) face}]×100.

Except for changing the O₂ gas flow rate during the first RTA treatment, the other conditions until completion of the second RTA treatment are the same as those in the first RTA treatment.

As described above, the PZT of which the (001) face is preferentially oriented has a largest polarization value. In terms of productivity of the FeRAM 1, it is preferable to preferentially orient a (111) face ((222) face) in which the switching direction forms an angle of 45° to the inversion electric field so that a relatively large polarization value can be obtained. From FIG. 3, it is found that when changing the O₂ gas flow rate during the first RTA treatment in a range of 15 sccm (0.75% by volume) to 35 sccm (1.75% by volume), the orientation rate in the PZT (222) face particularly increases at the O₂ gas flow rate of 25 sccm (1.25% by volume) and in the vicinity thereof. Further, from FIG. 4, it is found that when using this O₂ gas flow rate, relatively high switching electrical charges QSW can be obtained.

Therefore, in the case where the conditions for the first RTA treatment are optimized based on the crystal orientation property and polarization value of the PZT, it is only necessary to set the O₂ gas flow rate during the first RTA treatment to about 25 sccm (1.25% by volume), as is apparent from the results of FIGS. 3 and 4.

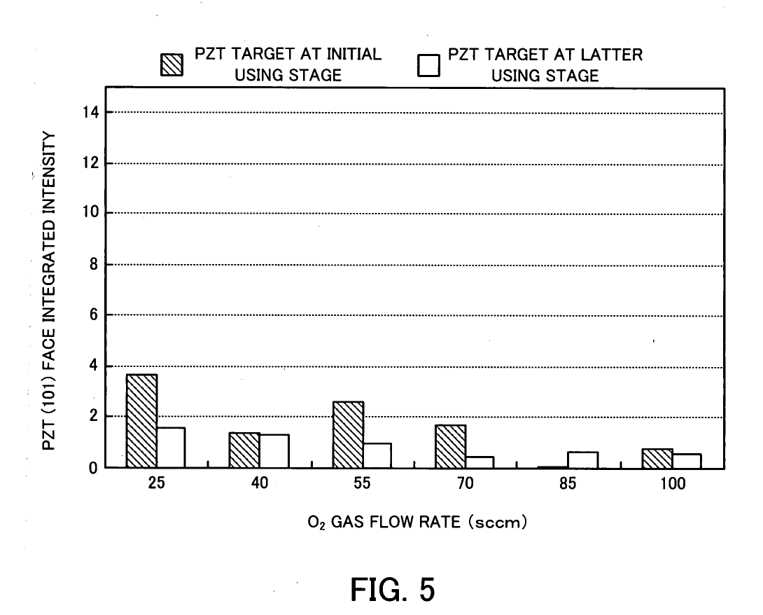

Subsequently, the results of study on the crystal orientation property of the PZT in a broader O₂ gas flow rate range are shown below. Herein, the first RTA treatment is performed under the conditions at about 563° C. for about 90 seconds in the same manner as in the above. That is, a wafer including the lower electrode layer 14 having sputtered thereon the PZT is set within a chamber of the lamp annealing device. Then, a mixed gas composed of an O₂ gas and an Ar gas is put in circulation while changing the O₂ gas flow rate in a range of 25 to 100 sccm to bring the total flow rate to 2000 sccm. Except for changing the O₂ gas flow rate during the first RTA treatment, the other conditions until completion of the second RTA treatment are the same as those in the first RTA treatment. The following FIGS. 5 to 7 show the measurement results on the crystal orientation property of the PZT when changing the O₂ gas flow rate during the first RTA treatment in a range of 25 sccm (1.25% by volume) to 100 sccm (5% by volume).

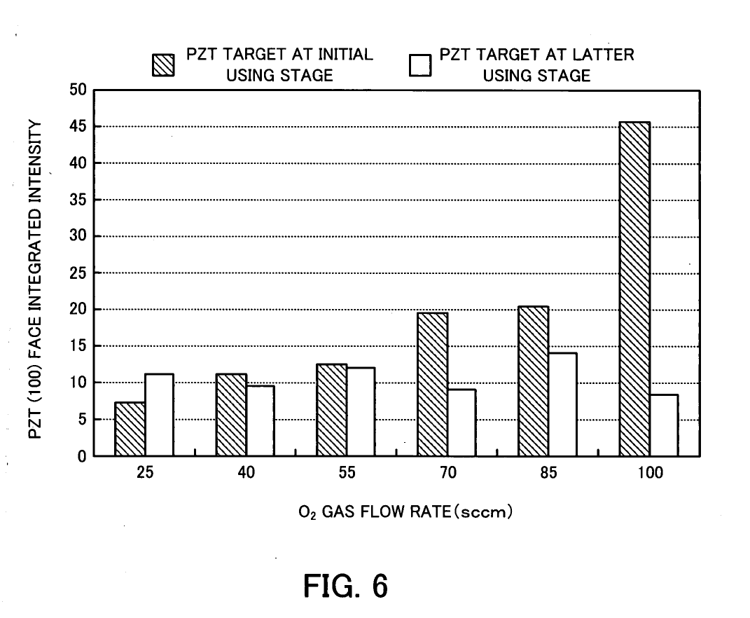

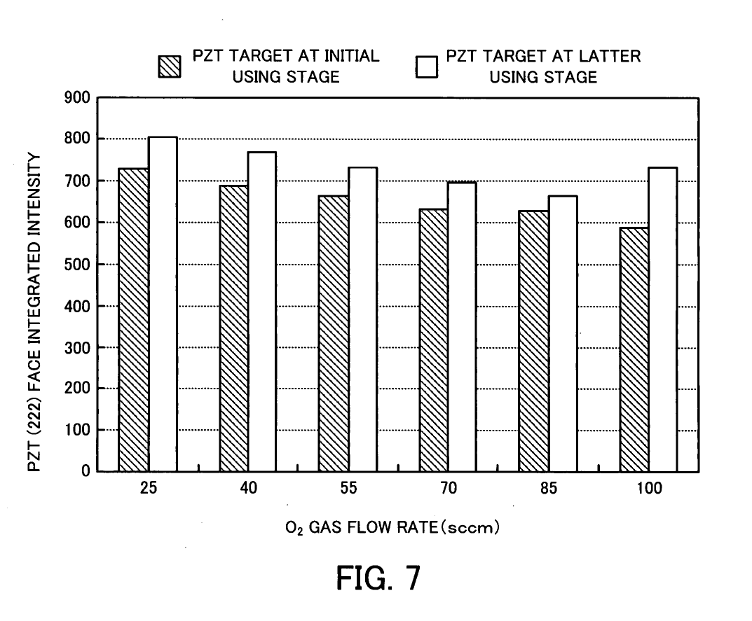

FIG. 5 shows a relationship between the O₂ gas flow rate during the first RTA treatment and the integrated intensity in the PZT (101) face. FIG. 6 shows a relationship between the O₂ gas flow rate during the first RTA treatment and the integrated intensity in the PZT (100) face. FIG. 7 shows a relationship between the O₂ gas flow rate during the first RTA treatment and the integrated intensity in the PZT (222) face. In the FIGS. 5 to 7, a horizontal axis shows the O₂ gas flow rate (sccm) during the first RTA treatment, and a vertical axis shows the integrated intensities in the respective crystal faces.

Further, FIGS. 5 to 7 also show collectively a relationship between the O₂ gas flow rate and the integrated intensities in the respective crystal faces in the following two cases. One case (initial using stage) is that the amount of the PZT target previously used during sputtering the PZT on the lower electrode layer 14 before the first RTA treatment performed while changing the O₂ gas flow rate is relatively small. The other case (latter using stage) is that the amount thereof is relatively large. The amount of the PZT target used is evaluated based on the electric energy (kWh) supplied to the PZT target. The PZT target in electric energy of 134.0 kWh is selected as that at the initial using stage. On the other hand, the PZT target in electric energy of 535.7 kWh is selected as that at the latter using stage.

From FIG. 5, the following tendencies are recognized. When the sputtering before the first RTA treatment is performed using the PZT target at the initial using stage, the integrated intensity in the PZT (101) face generally decreases with the increase of the O₂ gas flow rate, excluding the case where the O₂ gas flow rate is 40 sccm (2% by volume) or 85 sccm (4.25% by volume). Also when the sputtering before the first RTA treatment is performed using the PZT target at the latter using stage, the integrated intensity in the PZT (101) face generally decreases with the increase of the O₂ gas flow rate.

Further, excluding the case where the O₂ gas flow rate is 85 sccm (4.25% by volume), when the sputtering is performed using the PZT target at the latter using stage, the integrated intensity in the PZT (101) face decreases as compared with a case where the sputtering is performed using the PZT target at the initial using stage.

From FIG. 6, the following tendencies are recognized. When the sputtering before the first RTA treatment is performed using the PZT target at the initial using stage, the integrated intensity in the PZT (100) face increases with the increase of the O₂ gas flow rate. On the contrary, when the sputtering before the first RTA treatment is performed using the PZT target at the latter using stage, increase and decrease in the integrated intensity in the PZT (100) face are repeated with the increase of the O₂ gas flow rate.

Further, in the case where the O₂ gas flow rate is 25 sccm (1.25% by volume), when the sputtering is performed using the PZT target at the latter using stage, the integrated intensity in the PZT (100) face increases as compared with the case the sputtering is performed using the PZT target at the initial using stage. In the case where the O₂ gas flow rate is 40 sccm (2% by volume) or 55 sccm (2.75% by volume), the integrated intensities in the PZT (100) face are equal to each other in both cases of using the PZT target at the initial using stage and using the PZT target at the latter using stage. Further, in the case where the O₂ gas flow rate exceeds 70 sccm (3.5% by volume), when the sputtering is performed using the PZT target at the latter using stage, the integrated intensity in the PZT (100) face decreases as compared with the case where the sputtering is performed using the PZT target at the initial using stage.

From FIG. 7, the following tendencies are recognized. When the sputtering before the first RTA treatment is performed using the PZT target at the initial using stage, the integrated intensity in the PZT (222) face decreases with the increase of the O₂ gas flow rate. In the case where the O₂ gas flow rate is from 25 sccm (1.25% by volume) to 85 sccm (4.25% by volume), when the sputtering before the first RTA treatment is performed using the PZT target at the latter using stage, the integrated intensity in the PZT (222) face decreases with the increase of the O₂ gas flow rate. In the case where the O₂ gas flow rate is 100 sccm (5% by volume), the integrated intensity obtained is equal to that in the case where the O₂ gas flow rate is 55 sccm (2.75% by volume).

Further, in the case where the O₂ gas flow rate is from 25 sccm (1.25% by volume) to 100 sccm (5% by volume), when the sputtering is performed using the PZT target at the latter using stage, the integrated intensity in the PZT (222) face increases as compared with the case where the sputtering is performed using the PZT target at the initial using stage.

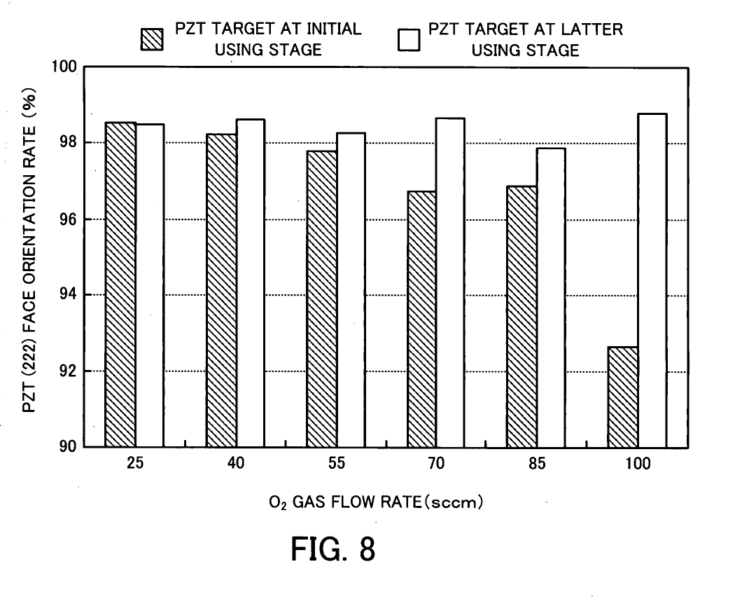

From the results in FIGS. 5 to 7, the orientation rate in the PZT (222) face at each O₂ gas flow rate during the first RTA treatment is determined in each of a case where the sputtering before the first RTA treatment is performed using the PZT target at the initial using stage and a case where the sputtering before the first RTA treatment is performed using the PZT target at the latter using stage. The results are shown in the following FIG. 8.

FIG. 8 shows a relationship between the O₂ gas flow rate during the first RTA treatment and the orientation rate in the PZT (222) face. In FIG. 8, a horizontal axis shows the O₂ gas flow rate (sccm) during the first RTA treatment, and a vertical axis shows the orientation rate (%) in the PZT (222) face.

The orientation rate (%) in the PZT (222) face shown in the FIG. 8 is calculated from the following formula: Orientation rate (%) in PZT (222) face={integrated intensity in PZT (222) face)/[{integrated intensity in PZT (100) face}+{integrated intensity in PZT (101) face}+{integrated intensity in PZT (222) face}]×100.

From FIG. 8, the following tendencies are recognized. In the case where the O₂ gas flow rate during the first RTA treatment is in a range of 25 sccm (1.25% by volume) to 100 sccm (5% by volume), when the sputtering before the first RTA treatment is performed using the PZT target at the initial using stage, the orientation rate in the PZT (222) face decreases with the increase of the O₂ gas flow rate during the first RTA treatment. In other words, in this case, the crystal orientation property deteriorates with the increase of the O₂ gas flow rate. On the contrary, when the sputtering before the first RTA treatment is performed using the PZT target at the latter using stage, the orientation rate in the PZT (222) face has a value as high as approximately 98%, regardless of the O₂ gas flow rates during the first RTA treatment.

On the other hand, in terms of electric characteristics, comparison is performed between the case where the sputtering before the first RTA treatment is performed using the PZT target at the initial using stage and the case where the sputtering is performed using the PZT target at the latter using stage. As a result, a difference is scarcely recognized at the time of checking of operations; however, a difference is recognized in the subsequent predetermined reliability test (a data holding property test after leaving the capacitors at high temperatures). The following Table 1 shows a relationship between the O₂ gas flow rate during the first RTA treatment and the yield of the ferroelectric capacitor 2. The yield is evaluated based on a ratio of capacitors (capacitors having fixed capacitor performance) allowed to pass a predetermined reliability test in the capacitors of which the operations are previously checked.

Yield (%)

| | PZT Target at | PZT Target at |
|---|---|---|
| O₂ Gas Flow Rate | Initial Using | Latter Using |
| (sccm) | Stage | Stage |
| 25 | 97.58 | 68.10 |
| 40 | 98.64 | 97.19 |
| 55 | 99.27 | 99.12 |
| 70 | 98.87 | 99.33 |
| 85 | 99.65 | 99.35 |
| 100 | 99.34 | 99.48 |

As is apparent from Table 1, in a case where the PZT target at the initial using stage is used for the sputtering before the first RTA treatment, a high yield is indicated regardless of the O₂ gas flow rate during the first RTA treatment. In other words, even if the O₂ gas flow rate during the first RTA treatment is increased to thereby deteriorate the crystal orientation property of the PZT (FIG. 8), a high yield can be kept so that the ferroelectric capacitor 2 having fixed capacitor performance can be stably formed. Particularly, when the O₂ gas flow rate during the first RTA treatment is from 25 sccm (1.25% by volume) to 55 sccm (2.75% by volume), the PZT crystal orientation property as well as the ferroelectric capacitor 2 yield are improved.

Further, as is apparent from Table 1, in the case where the PZT target at the latter using stage is used for the sputtering before the first RTA treatment, even if the O₂ gas flow rate during the first RTA treatment is 25 sccm (1.25% by volume), that is, the crystal orientation property of the PZT is high (FIG. 8), the yield of the ferroelectric capacitor 2 having fixed capacitor performance decreases. However, even in the case where the PZT target at the latter using stage is used for the sputtering, when the O₂ gas flow rate during the first RTA treatment is from 40 sccm (2% by volume) to 100 sccm (5% by volume), a high yield is indicated.

Thus, the O₂ gas flow rate during the first RTA treatment performed after the sputtering of the PZT has a large influence not only on the finally obtained crystal orientation property of the PZT but also on the yield of the ferroelectric capacitor 2.

Therefore, when forming the FeRAM 1 according to the flow shown in the FIG. 1, the following method may be employed. That is, after the sputtering of the PZT in the step S7, in other words, during the first RTA treatment in the step S8, the O₂ gas flow rate is set, for example, to 40 sccm (2% by volume) to 100 sccm (5% by volume). By employing this method, the ferroelectric capacitor 2 having predetermined capacitor performance can be formed with high yield, regardless of the amount of the PZT target previously used during the sputtering.

Alternatively, a method of managing the amount of the PZT target used in the formation of the FeRAM 1 may also be employed. More specifically, during the first RTA treatment in the step S8, the O₂ gas flow rate may be set as follows. That is, when the sputtering in the step S7 is performed using the PZT target at the initial using stage, the O₂ gas flow rate is set in an appropriate range. Only when the sputtering in the step S7 is performed using the PZT target at the latter using stage, the O₂ gas flow rate is set to 40 sccm (2% by volume) to 100 sccm (5% by volume). Also by employing this method, a ferroelectric capacitor having predetermined capacitor performance can be formed with high yield.

Accordingly, by employing the above-described methods, mass production of the FeRAM 1 can be more stably performed.

In the above description, a case of using the PZT as ferroelectric materials for constituting the dielectric layer 15 of the ferroelectric capacitor 2 is described by way of example. In addition to this, also in the case of using lanthanum doped lead zirconate titinate ((Pb, La) (Zr, Ti)O₃, PLZT) as ferroelectric materials, the same method can be employed as well as the same effect can be obtained.

Further, in the above description, the first and second RTA treatments are performed in an environment of an O₂/Ar mixed gas; however, a type of gas is not particularly limited thereto. Oxidizing gases other than an O₂ gas or nonoxidizing gases other than an Ar gas can also be used widely.

In the present invention, when forming the ferroelectric capacitor, the thermal treatment after forming the ferroelectric layer using the sputtering method is performed in an environment controlled such that predetermined capacitor performance can be obtained regardless of the amount of the target used in the sputtering method. As a result, the ferroelectric capacitor having predetermined capacitor performance can be formed with high yield. Further, the semiconductor device having the ferroelectric capacitor can be stably mass-produced.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

1. A method for forming a ferroelectric capacitor having a dielectric layer made of a ferroelectric material, comprising the steps of:
forming a lower electrode layer;
forming the ferroelectric layer on the lower electrode layer using a sputtering method;
performing, after formation of the ferroelectric layer, a thermal treatment under a condition of an oxygen partial pressure set such that predetermined capacitor performance can be obtained based on the amount of a target used in the sputtering method when forming the ferroelectric layer; and
forming at least a part of an upper electrode layer on the ferroelectric layer after the thermal treatment.

2. The method according to claim 1, wherein the predetermined capacitor performance includes at least a data holding property.

3. The method according to claim 1, wherein in the step of performing the thermal treatment, the thermal treatment is performed in an environment of a mixed gas composed of an oxygen gas in a range of 2% by volume to 5% by volume and an inert gas.

4. The method according to claim 1, wherein the thermal treatment is a RTA treatment.

5. The method according to claim 1, further comprising a step of performing a second thermal treatment after the step of forming at least a part of the upper electrode layer.

6. The method according to claim 5, wherein in the step of forming at least a part of the upper electrode layer, when forming only a part of the upper electrode layer, a remaining part thereof is formed on the partly formed upper electrode layer after the step of performing the second thermal treatment to thereby form the upper electrode layer.

7. The method according to claim 1, wherein the lower electrode layer has a laminated structure of an AL₂O₃ film and a Pt film.

8. The method according to claim 1, wherein the ferroelectric layer is a PZT layer or a PLZT layer.

9. A method for manufacturing a semiconductor device having a ferroelectric capacitor, comprising the steps of:
forming a lower electrode layer;
forming a ferroelectric layer on the lower electrode layer using a sputtering method;
performing, after formation of the ferroelectric layer, a thermal treatment under a condition of an oxygen partial pressure set such that predetermined capacitor performance can be obtained based on the amount of a target used in the sputtering method when forming the ferroelectric layer; and
forming at least a part of an upper electrode layer on the ferroelectric layer after the thermal treatment.

10. The method according to claim 9, wherein the predetermined capacitor performance includes at least a data holding property.

11. The method according to claim 9 wherein in the step of performing the thermal treatment, the thermal treatment is performed in an environment of a mixed gas composed of an oxygen gas in a range of 2% by volume to 5% by volume and an inert gas.

12. The method according to claim 9, wherein the thermal treatment is a RTA treatment.

13. The method according to claim 9, further comprising a step of performing a second thermal treatment after the step of forming at least a part of the upper electrode layer.

14. The method according to claim 13, wherein in the step of forming at least a part of the upper electrode layer, when forming only a part of the upper electrode layer, a remaining part thereof is formed on the partly formed upper electrode layer after the step of performing the second thermal treatment to thereby form the upper electrode layer.

15. The method according to claim 9, wherein the lower electrode layer has a laminated structure of an AL₂O₃ film and a Pt film.

16. The method according to claim 9, wherein the ferroelectric layer is a PZT layer or a PLZT layer.
